(19) United States
(12) Patent Application Publication
(10) Pub. No.: US 2008/0137542 A1
(43) Pub. Date: Jun. 12, 2008

(54) Method for detecting abnormal network packets

(75) Inventor: Shih-Hua Chiu, Taipei (TW)

Correspondence Address: BACON & THOMAS, PLLC, 625 SLATERS LANE, FOURTH FLOOR, ALEXANDRIA, VA, 22314, US

(73) Assignee: INVENTEC CORPORATION, Taipei (TW)

(21) Appl. No.: 11/636,491

(22) Filed: Dec. 11, 2006

(51) Int. Cl. G01R 31/08

(52) U.S. Cl. 370/242

(57) ABSTRACT

The present invention discloses a method for detecting abnormal network packets, which is applied to a packet distributing unit in a network. The packet distributing unit exchanges a plurality of network packets with a plurality of network devices on an extranet, and records a destination IP address, a destination port number and a network packet output time of the network packets specifically outputted within at least two time periods, every time before the packet distributing unit sends these specific output network packets out, then the packet distributing unit compares these specific output network packets in different time periods to determine whether or not there are data having the same output time, same destination IP address and same destination port number; if yes, then the packet distributing unit issues a warning report.

### FIELD OF THE INVENTION

The present invention relates to a method for detecting abnormal network packets, and more particularly to a method applied to a packet distributing unit in a network for recording destination IP addresses, destination port numbers and network packet output time of network packets specifically outputted within a first time period and a second time period into a first data and a second data, and comparing the data obtained within the two different time periods to determine whether or not the data has the same output time, destination IP address and destination port number; if yes, then issuing a warning report.

### BACKGROUND OF THE INVENTION

As the electronic industry blooms and electronic products become indispensable to our life, various electronic products derived from the network technologies provide many breakthroughs to the development of science and technologies. With constant researches and advancements of the network products, the issue and consideration related to the network safety become increasingly important, particularly when the servers of many major corporations and organization are invaded or damaged by computer viruses, worms or Spyware (such as the Troy virus), or their confidential information and data are stolen via the Internet, and thus competitions among the major antivirus companies become very severe in the network safety market.

At present, major antivirus companies introduce different detection programs for the virus codes of different Spyware created by hackers, and these detection programs can scan Spyware, warn users about viruses, and delete viruses. In general, network management personnel will report to an antivirus company about any virus of Spyware occurred in their servers, and detection software with an appropriate solution will be developed. However, it is necessary to wait till the antivirus company to discover the brand new Spyware and develop antivirus codes for such Spyware before individual or corporate users can protect their data from being stolen, and irrecoverable damages may occur long before any protection measure can be taken place. Therefore, finding a method of detecting abnormal network packets, such that servers of corporations and organizations no longer have to wait passively for the break out of a brand new Spyware or virus, the discovery of such new Spyware or virus and appropriate actions for the Spyware or virus demands immediate attentions and feasible solutions.

### SUMMARY OF THE INVENTION

In view of the foregoing shortcomings of the prior art, the inventor of the present invention based on years of experience and professional knowledge in the related field to conduct experiments and modifications, and finally invented a method for detecting abnormal network packets in accordance with the present invention, so as to block Spyware and prevent damages caused by Spyware.

Therefore, it is a primary objective of the present invention to provide a method for detecting abnormal network packets which is applied to a packet distributing unit in a network. The packet distributing unit exchanges a plurality of network packets with a plurality of network devices on an extranet and records destination IP addresses, destination port numbers and network packet output time of the network packets specifically outputted within a first time period and a second time period, into a first data and a second data every time before the packet distributing unit sends these specific output network packets out, and then the packet distributing unit compares these specific output network packets in different time periods to determine whether or not the data have the same output time, destination IP address and destination port number; if yes, then the packet distributing unit issues a warning report.

To make it easier for our examiner to understand the objective, technical characteristics and effects of the present invention, preferred embodiments will be described with accompanying drawings as follows:

### BRIEF DESCRIPTION OF THE DRAWINGS

FIG. 1 is a schematic block diagram of the present invention;

FIG. 2 is a schematic view of an output packet data module of the present invention;

FIG. 3 is a flow chart of comparing network packets by a packet distributing unit in accordance with the present invention;

FIG. 4 is a flow chart of using a temporary table to compare output network packets by a packet distributing unit in accordance with the present invention;

FIG. 5 is a flow chart of comparing TCP sequence numbers of output network packets by a packet distributing unit in accordance with the present invention;

FIG. 6 is a schematic view of a filter table of the present invention;

FIG. 7 is a flow chart of using a filter table to compare output network packets by a packet distributing unit in accordance with the present invention; and

FIG. 8 is a schematic view of an abnormal warning module of the present invention.

### DETAILED DESCRIPTION OF THE PREFERRED EMBODIMENTS

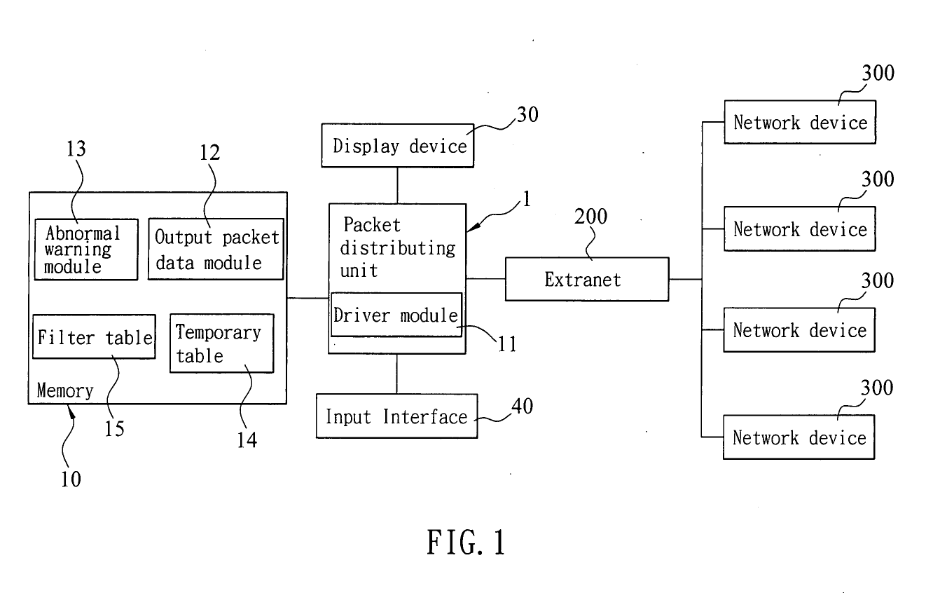

Referring to FIG. 1 for a method for detecting abnormal network packets, the method is applied to a packet distributing unit 1 on a network, and the packet distributing unit 1 (such as a server, a server card or a network card) is provided for receiving a plurality of network packets, and exchanging network packets with a plurality of network devices 300 (such as a server) over an extranet 200 (such as the Internet). When the packet distributing unit 1 distributes the network packets to the network devices 300, the packet distributing unit 1 de-capsulates the network packets one by one to obtain a source IP address, a source port number, a destination IP address and a destination port number thereof, and separately records specific destination IP addresses and destination port numbers of network packets specifically outputted within a first time period and a second time period and output time (which is a post time) of the specific output network packets. The packet distributing unit 1 also compares the network packets in different time periods and determines whether or not the data has the same output time, destination IP address and destination port number; if yes, then the packet distributing unit 1 will issue a warning report to alert the occurrence of abnormal network packets.

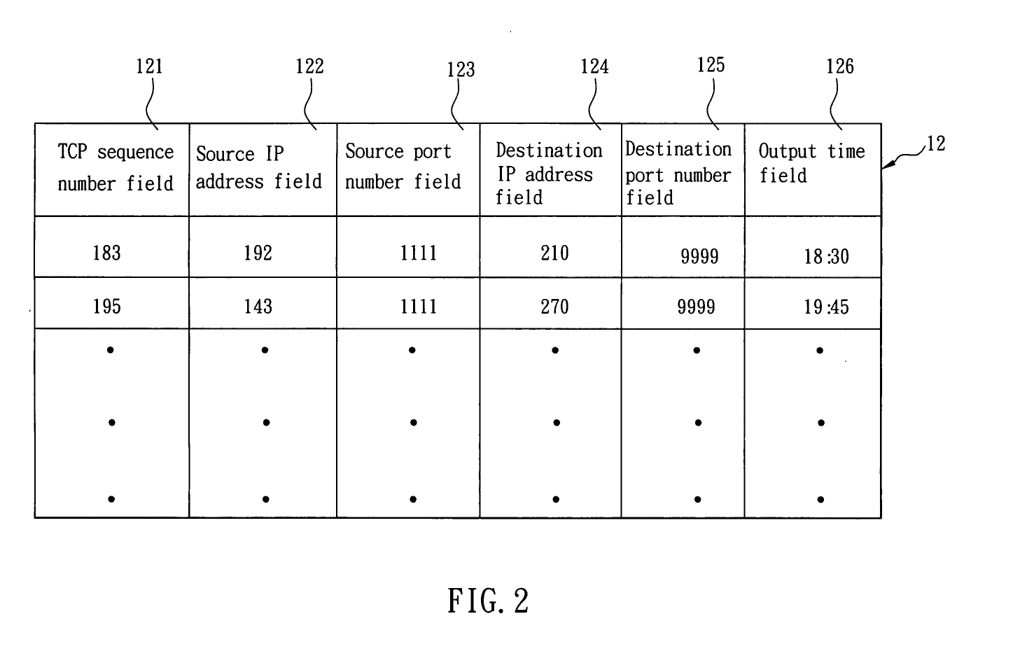

Referring to FIGS. 1 and 2 for a preferred embodiment of the present invention, the packet distributing unit 1 comprises a driver module 11 which is a driver installed in the packet distributing unit 1, and the packet distributing unit 1 includes a memory 10 connected internally or externally with the packet distributing unit 1, and the memory 10 includes an output packet data module 12 and an abnormal warning module 13, and the output packet data module 12 is provided for recording the data such as a TCP sequence number field 121, a source IP address field 122, a source port number field 123, a destination IP address field 124, a destination port number field 125 and an output time (which is a system time) field 126 of the output network packets.

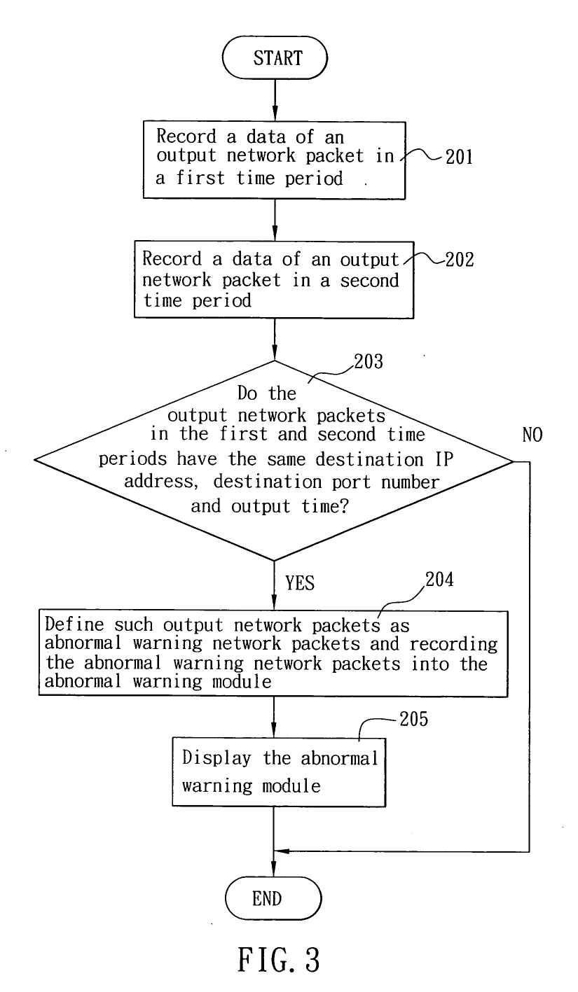

Referring to FIG. 3, the packet distributing unit 1 carries out the following steps within a time period:

Step (201): If an event of an output network packet is occurred in a first time period, then the packet distributing unit 1 will record a TCP sequence number, a source IP address, a source port number, a destination IP address, a destination port number and an output time of the specific output network packet into the output packet data module 12 as a first data.

Step (202): If an event of an output network packet is occurred in a second time period, then the packet distributing unit 1 will record a TCP sequence number, a source IP address, a source port number, a destination IP address, a destination port number and an output time of the specific output network packet into the output packet data module 12 as a second data.

Step (203): An AND operation of the Boolean logic is used for comparing the destination IP addresses, destination port numbers and output time of the output network packets outputted within the first time period and the second time period to determine whether or not these network packets have the same destination IP address, destination port number and output time; if yes, then go to Step (204), or else end this procedure.

Step (204): Each network packet having the same destination IP address, destination port number and output time is defined as an abnormal network packet and recorded into an abnormal warning module 13.

Step (205): The abnormal warning module 13 shows a screen and displays the screen on a display device 30.

Due to coincidence or other reasons, it is very often to output network packets to the same network device 300 at the same time within two time periods. To avoid such coincidence or improve accuracy, the method of the present invention can use the data of output network packets recorded in three or more time periods for comparisons, and the comparison adopts an AND operation of the data recorded in different time periods.

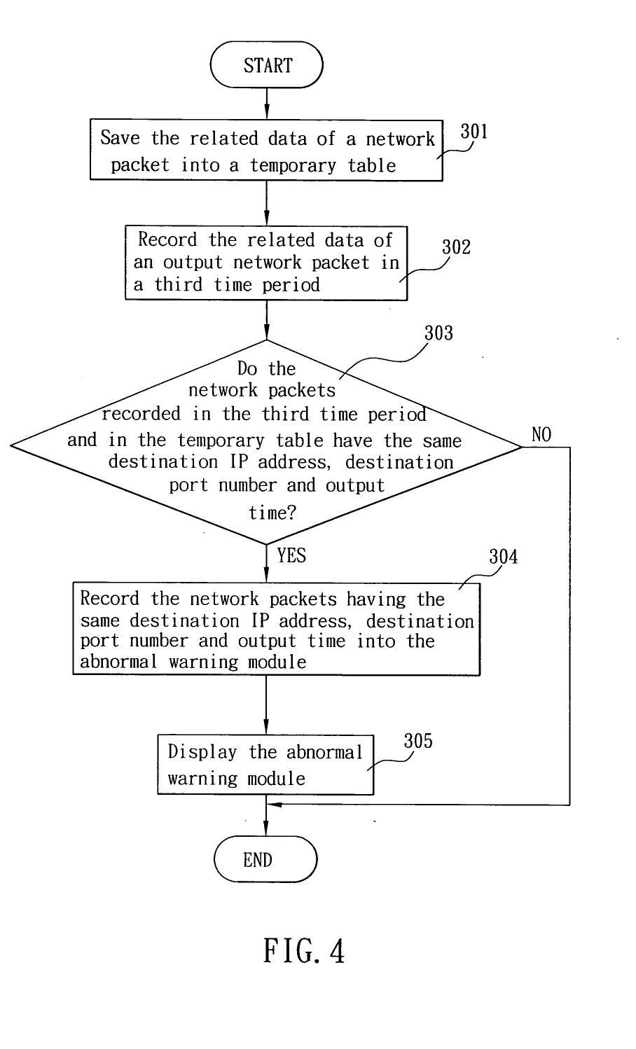

Referring to FIG. 4 for a method of another preferred embodiment of the present invention, the data of output network packets recorded in three time periods are compared, and the packet distributing unit 1 carries out the following steps:

Step (301): The TCP sequence number, source IP address, source port number, destination IP address, destination port number and output time of a packet of the network packets recorded in the first and second time periods are compared, and the result (including the destination IP address, destination port number and output time) of the network packets computed by an AND operation is recorded into a temporary table 14 of the memory 10.

Step (302): If an event of an output network packet is occurred in a third time period, then the packet distributing unit 1 will output the destination IP address, destination port number and output time of the network packets into the output packet data module 12.

Step (303): The data of the temporary table 14 are compared with the destination IP address, destination port number and output time of the network packets recorded in the third time period to determine whether or not the network packets have the same destination IP address, destination port number and output time; if yes, then go to Step (304), or else end this procedure.

Step (304): The network packets having the same destination IP address, destination port number and output time are defined as abnormal network packets and recorded into the abnormal warning module 13.

Step (305): The abnormal warning module shows a screen and displays the screen on the display device 30.

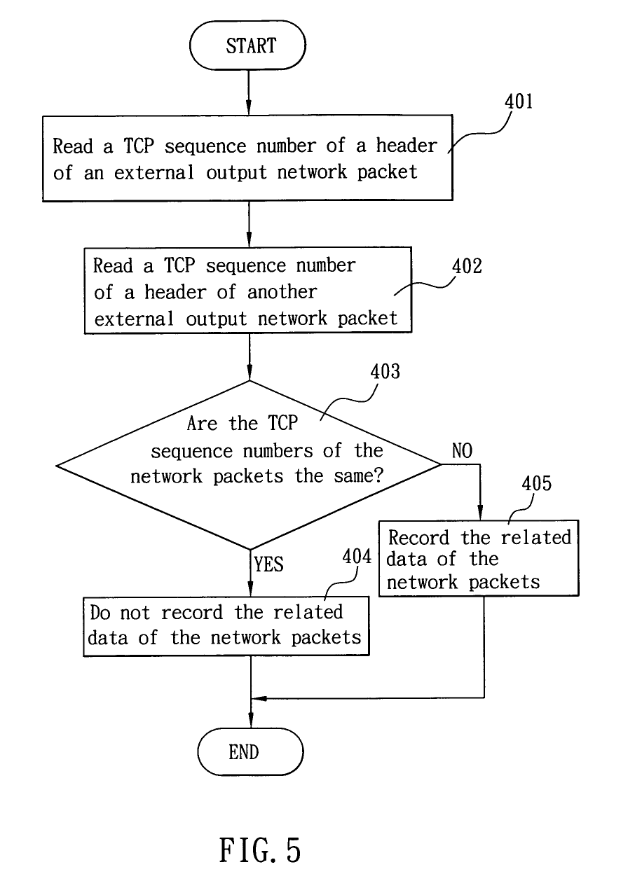

In FIG. 1, a single record of data sent to each network device 300 is divided into a plurality of network packets having the same TCP sequence number. If the data is an abnormal data issued by an abnormal program, all network packets having the same TCP sequence number will be recorded in the output packet data module 12, and such arrangement wastes tremendous resources of the packet distributing unit 1, since it is not necessary to record all network packets having the same header into the output packet data module 12. To avoid wasting resources or repeatedly recording the same TCP sequence number, the packet distributing unit 1 determines whether or not the network packets are packets of the same data based on the same TCP sequence number of each network packet. The foregoing specific output network packet is defined as any first output network packet having the same TCP sequence number of the network packets. Before the packet distributing unit 1 records the destination IP address, destination port number and output time of the network packets in each time period as shown in FIG. 5, the packet distributing unit 1 carries out a procedure comprising the steps of:

Step (401): reading a TCP sequence number in a header for an external output network packet;

Step (402): reading a TCP sequence number in a header for another external output network packet;

Step (403): determining whether or not the TCP sequence numbers of the network packets are the same; if yes, then go to Step (404), or else go to Step (405);

Step (404): not recording the destination IP address, destination port number and output time of the network packets into the output packet data module 12.

Step (405): recording the destination IP address, destination port number and output time of the network packets into the output packet data module 12.

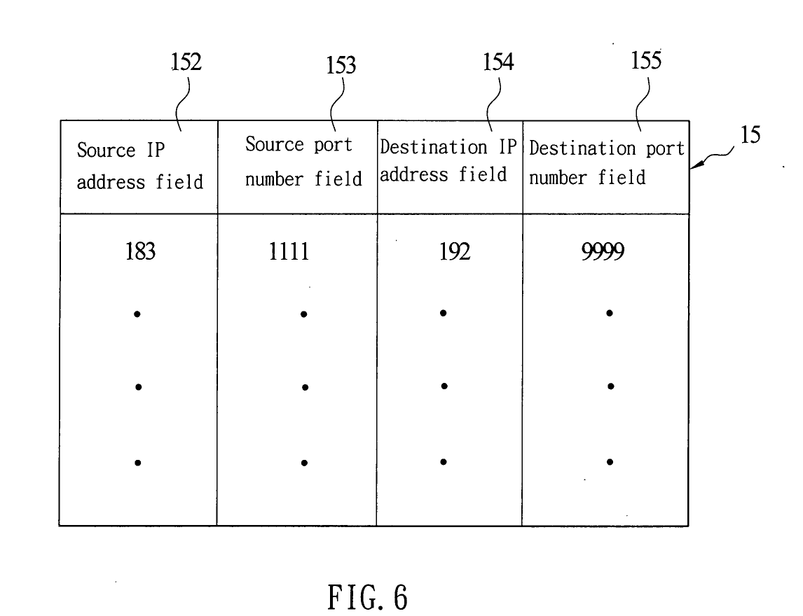

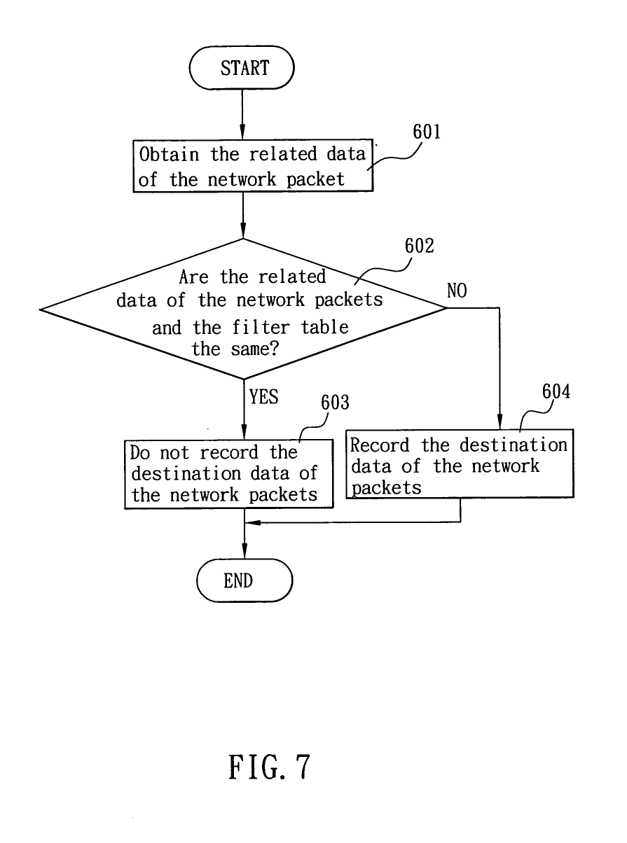

In FIGS. 1 and 6, the packet distributing unit 1 of the foregoing preferred embodiment expedites the efficiency of recording the data of network packets, and the memory 10 further includes a filter table 15, and the data in the filter table 15 are provided for the packet distributing unit 1 as a basis for determining a normal network packet (such as a packet at the source IP address or the destination IP address) that needs not to be recorded. The foregoing specific output network packets are defined as data incompliance with a data recorded in the filter table 15. The filter table 15 includes a source IP address field 152, a source port number field 153, a destination IP address field 154 and a destination port number field 155, and the filter table 15 also can provide an input interface 40 at the display device 30 for users to make corrections to the data of network packets for normal transmissions. In FIG. 7, the packet distributing unit 1 outputs a network packet and carries out a procedure comprising the steps of:

Step (601): obtaining a source IP address, a source port number, a destination IP address and a destination port number of a network packet;

Step (602): determining whether or not a destination IP address and a destination port number of the output network packet are in compliance with the data in the filter table 15; if yes, then go to Step (603), or else go to Step (604);

Step (603): not recording the destination IP address and the destination port number of the network packets into the output packet data module 12.

Step (604): recording the data of the network packets into the output packet data module 12.

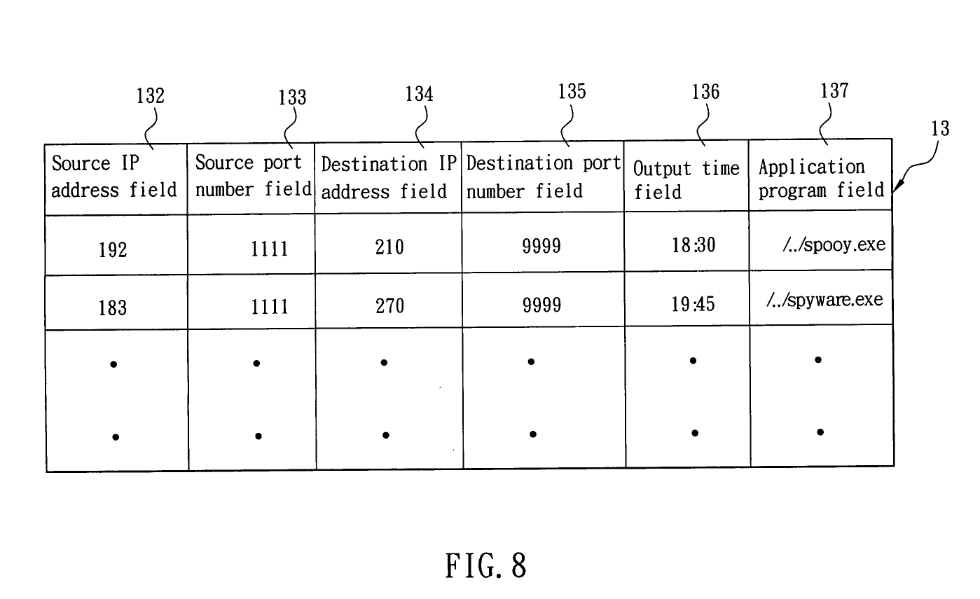

Referring to FIGS. 1 and 8, the abnormal warning module 13 could be an abnormal warning table stored in the memory 10, which comprises a source IP address field 132, a source port number field 133, a destination IP address field 134, a destination port number field 135, an output time field 136 and an application program field 137. When the packet distributing unit 1 records the destination IP address, destination port number and output time of each abnormal network packet into the abnormal warning module 13, the packet distributing unit 1 also records the source IP address and source port number of the specific output network packets outputted within at least two time periods, and the packet distributing unit 1 will locate an application program that issues the network packets based on the destination IP address and the destination port number of the address field 132 and the source port number field 133 of the source IP address in the abnormal warning module 13, and will input a file path of the application program into an application program field 137 of the abnormal warning module.

The present invention has been shown and described in detail, various modifications and improvements thereof will become readily apparent to those skilled in the art. Accordingly, the spirit and scope of the present invention is to be construed broadly and limited only by the appended claims and not by the foregoing specification.

What is claimed is:

1. A method for detecting abnormal network packets, which is applied to a packet distributing unit in a network for exchanging a plurality of network packets, each of said network packets including a destination IP address, a destination port number, a source IP address and a source port number, with a plurality of network devices on an extranet, comprising the steps of:
recording said destination IP addresses, said destination port numbers and an output time of said network packets specifically outputted within a first time period into a first data;
recording said destination IP address, said destination port number and an output time of said network packets specifically outputted within a second time period into a second data;
comparing said first data and said second data to determine whether or not said first and second data have the same output time, destination IP address and destination port number; and
if yes, then issuing a warning report.

2. The method of claim 1, wherein said destination IP address, said destination port number and said output time of said network packets specifically outputted within said first and second time periods are recorded into an output packet data module.

3. The method of claim 2, further comprising the steps of:
defining said specific output network packets having the same destination IP address, destination port number and output time as abnormal network packets;
recording said abnormal network packets into an abnormal warning module; and
allowing said abnormal warning module to show a screen and displaying said screen on a display device.

4. The method of claim 2, wherein said first and second data within different time periods are compared by an AND operation.

5. The method of claim 4, wherein said packet distributing unit further comprises a filter table provided to said packet distributing unit as a basis for determining a normal network packet that needs not to be recorded, and said specific output network packets are incompliance with the data of said filter table.

6. The method of claim 4, wherein said output network packet includes a TCP sequence number of said network packet, and said specific output network packet is any first output network packet having the same TCP sequence number of said network packet.

7. The method of claim 5, wherein when said source IP addresses and said source port numbers of said specific output network packets within said first and second time periods are recorded, further comprises the steps of:
recording said source IP addresses and said source port numbers of said abnormal network packets into said abnormal warning module;
locating an application program that issues said network packets, based on said source IP addresses and said source port numbers in said abnormal warning module; and
inputting a file path of said application program into said abnormal warning module.

8. The method of claim 6, wherein when said source IP address and said source port number of said specific output network packets within said first and second time periods are recorded, further comprises the steps of:
recording said source IP addresses and said source port numbers of said abnormal network packets into said abnormal warning module;
locating an application program that issues said network packets, based on said source IP addresses and said source port numbers in said abnormal warning module; and
inputting a file path of said application program into said abnormal warning module.
